(19) United States
(12) Patent Application Publication
(10) Pub. No.: US 2015/0055296 A1
(43) Pub. Date: Feb. 26, 2015

(54) AIR GUIDING STRUCTURE, SUBSTRATE, AND ELECTRONIC DEVICE

(71) Applicant: FUJITSU LIMITED, Kawasaki-shi (JP)

(72) Inventors: Kenji JOKO, Yokohama (JP); Osamu Saito, Kawasaki (JP); Hideaki Matsumoto, Yokohama (JP); Mitsuaki Hayashi, Kawasaki (JP); Takaharu Izuno, Kawasaki (JP); Minoru Fujii, Kawasaki (JP)

(73) Assignee: FUJITSU LIMITED, Kawasaki-shi (JP)

(21) Appl. No.: 14/322,030

(22) Filed: Jul. 2, 2014

(30) Foreign Application Priority Data
Aug. 21, 2013 (JP) 2013-171227

(51) Int. Cl. H05K 7/20

(52) U.S. Cl. CPC H05K 7/20145
USPC 361/695; 165/96

(57) ABSTRACT

An air guiding structure includes a shaft that is provided on a substrate body in an upright manner; a baffle plate coupled to the shaft so as to rotate around the shaft, the baffle plate guiding air that has been introduced into the substrate body; and a rotation restricting member that restricts a rotation of the baffle plate caused by the air that has been introduced.

### CROSS-REFERENCE TO RELATED APPLICATION

This application is based upon and claims the benefit of priority of the prior Japanese Patent Application No. 2013-171227, filed on Aug. 21, 2013, the entire contents of which are incorporated herein by reference.

### FIELD

The embodiments discussed herein are related to an air guiding structure, a substrate, and an electronic device.

### BACKGROUND

Some electronic devices in which a substrate is mounted adopt a structure that cools an element on the substrate by introducing air to the substrate. In such a case, there is used a technique for regulating the airflow by providing the substrate with a baffle board or the like (see Japanese Laid-open Patent Publication No. 2004-200344, for example).

### SUMMARY

According to an aspect of the invention, an air guiding structure includes a shaft that is provided on a substrate body in an upright manner, a baffle plate coupled to the shaft so as to rotate around the shaft, the baffle plate guiding air that has been introduced into the substrate body, and a rotation restricting member that restricts a rotation of the baffle plate caused by the air that has been introduced.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is an exploded perspective view illustrating an air guiding structure of a first exemplary embodiment together with a portion of a substrate body;

FIG. 2 is a perspective view illustrating a substrate of the first exemplary embodiment in a vertical state;

FIG. 3 is a perspective view illustrating a vertical mounting device of the first exemplary embodiment;

FIG. 4 is a perspective view illustrating a horizontal mounting device of the first exemplary embodiment;

FIG. 5 is an explanatory drawing illustrating a state in which the substrate of the first exemplary embodiment is mounted in the vertical mounting device;

FIG. 6 is an explanatory drawing illustrating a state in which the substrate of the first exemplary embodiment is mounted in the horizontal mounting device;

FIGS. 7A to 7D are explanatory drawings sequentially illustrating from FIGS. 7A to 7D a baffle plate of an air guiding structure of the first exemplary embodiment rotating in response to the change in position of the substrate from a horizontal state to a vertical state;

FIGS. 8A to 8D are explanatory drawings sequentially illustrating from FIGS. 8A to 8D the baffle plate of the air guiding structure of the first exemplary embodiment rotating in response to the change in position of the substrate from a vertical state to a horizontal state;

FIG. 9 is an exploded perspective view illustrating an air guiding structure of a second exemplary embodiment together with a portion of the substrate body;

FIGS. 10A to 10D are explanatory drawings sequentially illustrating from FIGS. 10A to 10D a baffle plate of an air guiding structure of the second exemplary embodiment rotating in response to the change in position of the substrate from a horizontal state to a vertical state;

FIGS. 11A to 11D are explanatory drawings sequentially illustrating from FIGS. 11A to 11D the baffle plate of the air guiding structure of the second exemplary embodiment rotating in response to the change in position of the substrate from a vertical state to a horizontal state; and

FIG. 12 is an exploded perspective view illustrating an air guiding structure of the third exemplary embodiment together with a portion of the substrate body.

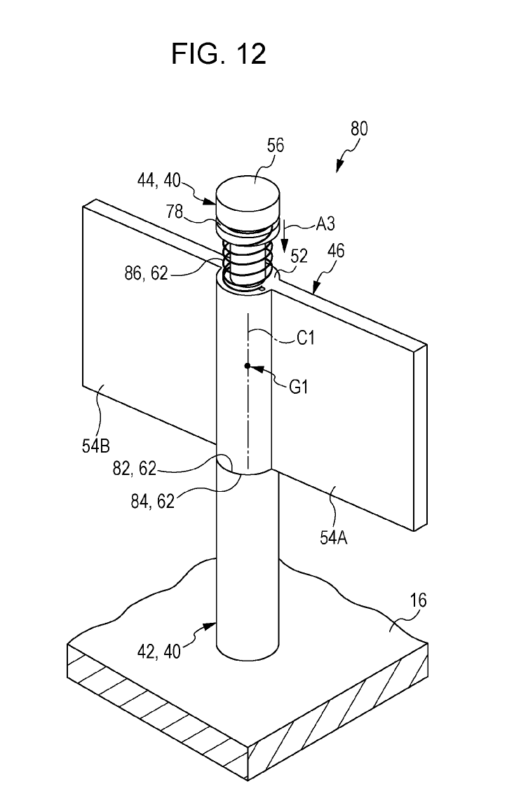

### DESCRIPTION OF EMBODIMENTS

In electronic devices, the direction in which cooling air is introduced to a substrate varies according to the arrangement of a fan and an air introduction port that introduce air. The positions of the fan and the air introduction port relative to the substrate vary in cases of an electric device in which a substrate is mounted in the horizontal direction and an electric device in which a substrate is mounted in the vertical direction; accordingly, there are cases in which the direction of the air flowing along the substrate differs and, further, there are cases in which the distribution of air velocity becomes uneven.

As a result, depending on the direction in which the substrate is mounted, there are cases in which the flow of air is not optimum; accordingly, the efficiency accordingly, the efficiency with which the element is cooled, the cooling including dissipation of heat by the element mounted on the substrate, may decrease.

Accordingly, the efficiency that is achieved by applying the same substrate to both kinds of device, namely, a device in which the substrate is mounted in the vertical direction and a device in which the substrate is mounted in the horizontal direction, may be hindered.

Accordingly, it is desirable that, regardless of the direction in which the air is introduced, the air is guided to flow in the desired direction at portions along the substrate. However, the baffle boards described above are fixed to the substrate body, for example; accordingly, the airflow direction is not capable of being controlled and the substrate has little versatility.

Further it is preferable to increase the versatility of the substrate by adapting to the direction in which the air is introduced to the substrate so as to guide the air along the substrate in the desired direction.

A first exemplary embodiment will be described in detail with reference to the drawings.

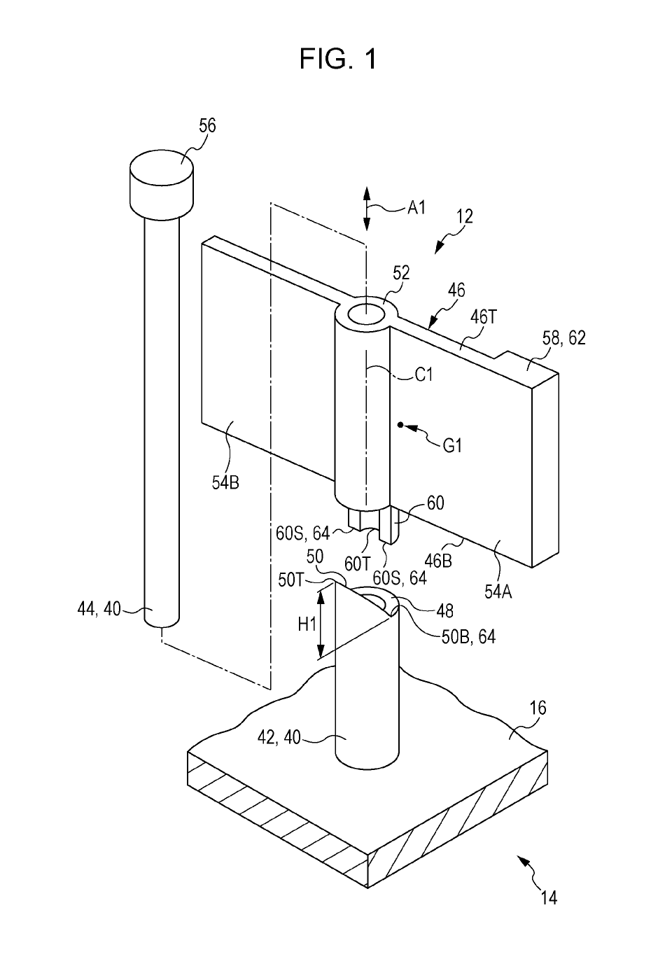

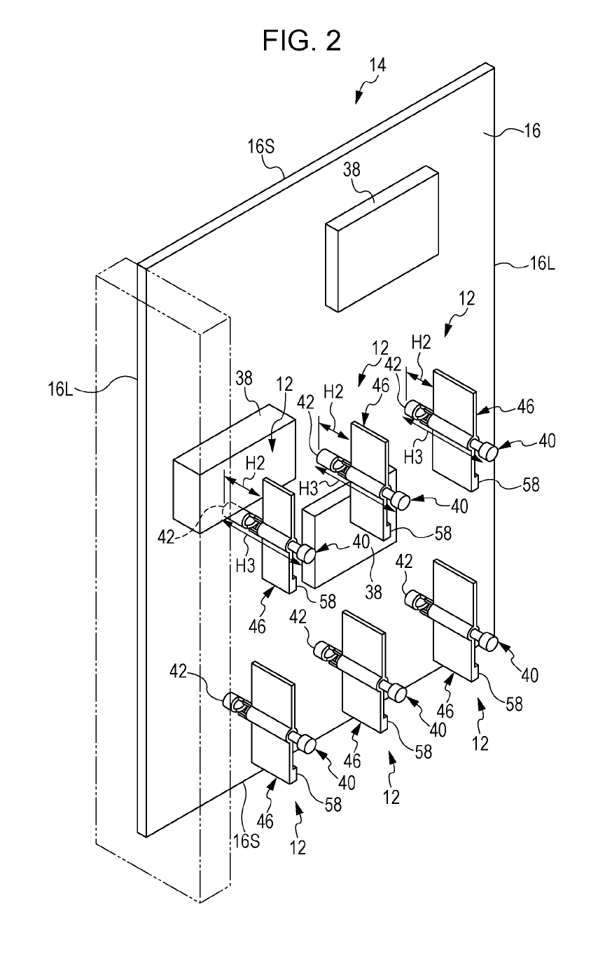

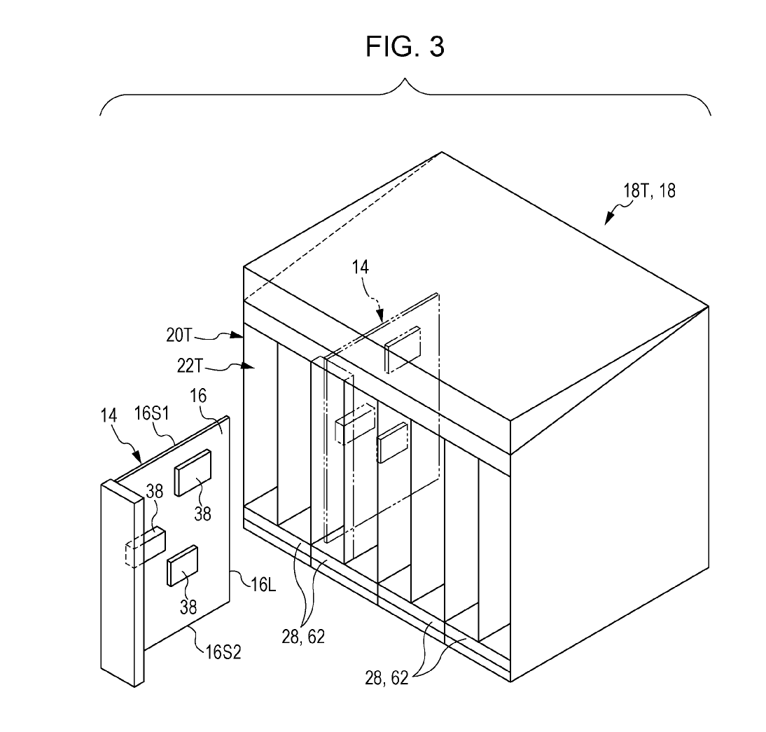

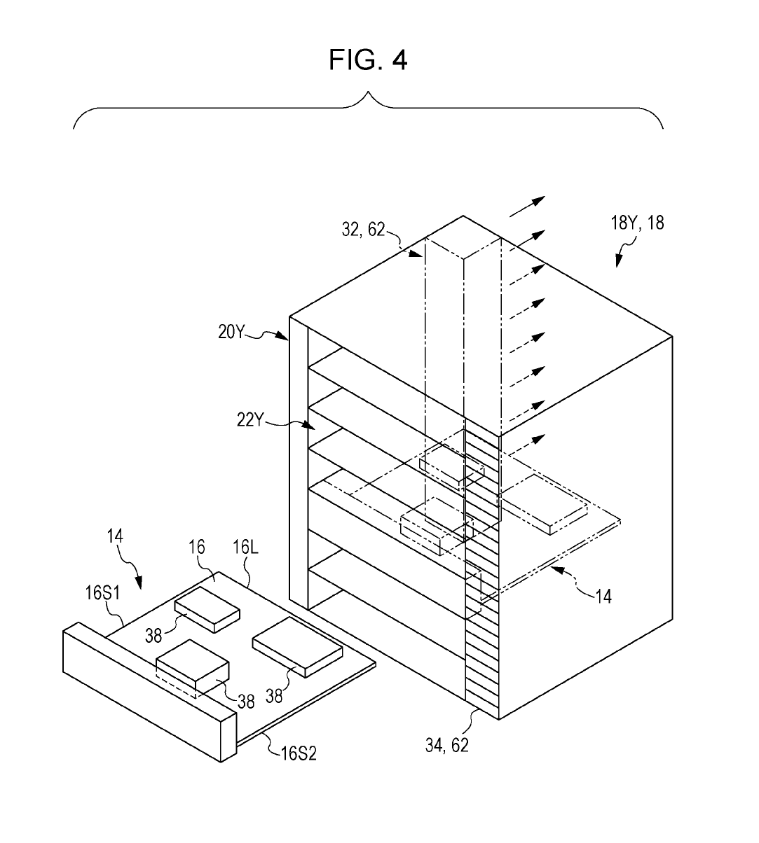

FIG. 1 illustrates an air guiding structure 12 of the first exemplary embodiment together with a portion of a substrate body 16. FIG. 2 illustrates a substrate 14 including the air guiding structures 12 and the substrate body 16. Furthermore, FIGS. 3 and 4 each illustrate a mounting device 18 in which the substrates 14 are mounted. The mounting device 18 is an example of an electronic device. The mounting devices 18 each include a box-shaped housing 20T or 20Y.

The mounting device 18 illustrated in FIG. 3 is structured so that the substrates 14 are mounted vertically; hereinafter, for convenience, the mounting device 18 is referred to as a vertical mounting device 18T. On the other hand, the mounting device 18 illustrated in FIG. 4 is structured so that the substrates 14 are mounted horizontally; accordingly, for convenience, the mounting device 18 is referred to as a horizontal mounting device 18Y. In FIGS. 3 and 4, illustration of the air guiding structures 12 is omitted.

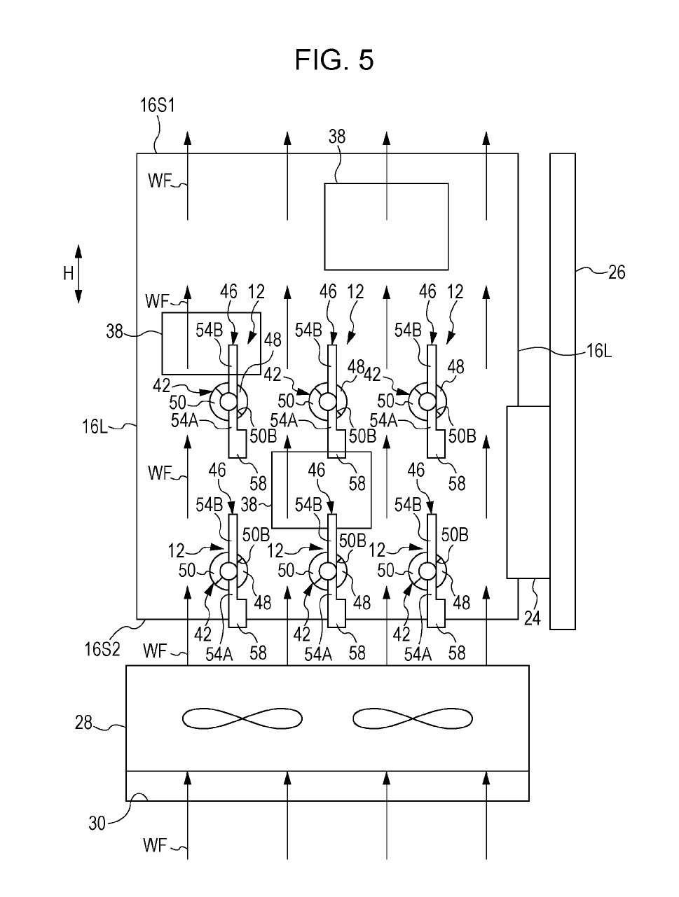

A housing 20T of the vertical mounting device 18T illustrated in FIG. 3 is capable of mounting a plurality of substrates 14 upright in a vertical manner with predetermined or certain spaces therebetween in the lateral direction. In the housing 20T, at the far side of each mounting area 22T and at the far side of each substrate 14, there is arranged a back substrate 26 (see FIG. 5) that connects the plurality of substrates 14 thereto via connectors 24.

Intake fans 28 are attached below the mounting areas 22T of the substrates 14 and, further, intake ports 30 (see FIG. 5) are provided below the intake fans 28. In the vertical mounting device 18T, since there are no other components above and below the mounting areas 22T, the intake fans 28 and the intake ports 30 may be arranged substantially throughout the whole mounting areas 22T. The intake fans 28 and the intake ports 30 may be referred to as air introducing devices 62 of the vertical mounting device 18T as well.

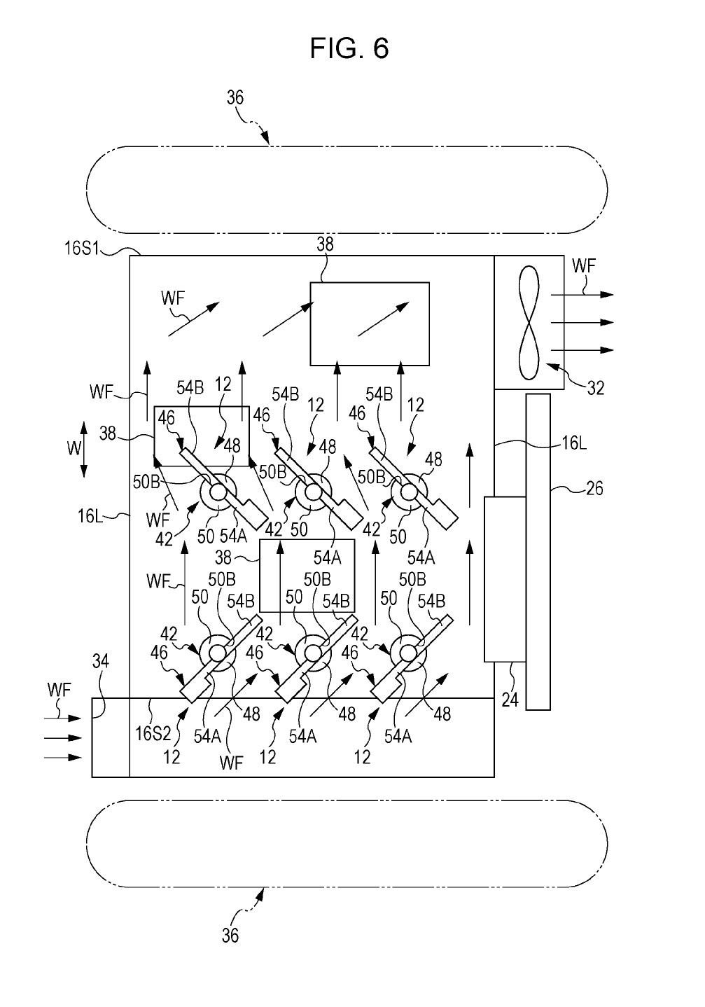

The housing 20Y of the horizontal mounting device 18Y illustrated in FIG. 4 is capable of mounting a plurality of substrates 14 in a horizontal state with predetermined or certain spaces therebetween in the up-down direction. In the housing 20Y, at the far side of each mounting area 22Y and at the far side of each substrate 14, a back substrate 26 (see FIG. 6) that connects the plurality of substrates 14 thereto via connectors 24 is arranged.

As illustrated in FIG. 6, areas 36 for disposing other components, for example, an area in which to arrange wiring cables, are formed next to the left and right portions of the mounting areas 22Y of the substrates 14. Accordingly, exhaust fans 32 are provided at the far sides of the mounting areas 22Y on one side of the substrates 14 in the width direction at positions avoiding the back substrate 26. Furthermore, intake ports 34 are provided at the near sides of the mounting areas 22Y on the other side of the substrates 14 in the width direction. The exhaust fans 32 and the intake ports 34 may be referred to as air introducing devices 62 of the horizontal mounting device 18Y as well.

As illustrated in FIG. 2, each substrate 14 includes the plate-shaped substrate body 16. In the present exemplary embodiment, the substrate body 16 is formed in a substantially rectangular shape and, for convenience, the short sides 16S and the long sides 16L will be distinguished from each other. Furthermore, as illustrated in FIG. 5, the short side 16S is referred to as a short side 16S1 when the short side 16s becomes the upper side at being mounted in the vertical mounting device 18T. The short side 16S that becomes the lower side is referred to as a short side 16S2 such that they are distinguished from each other. However, when no distinguishment is made between the two, they will each be merely referred to as the short side 16S. The directions in which the substrate body 16 is mounted in the mounting device 18T and 18Y are determined by the relationship with the mounting area 22T and 22Y, respectively. Furthermore, the substrate body 16 may have a square shape.

A variety of elements 38 are disposed on the substrate body 16. The elements 38 are electrically coupled to one another with a predetermined or certain wiring pattern or the like.

A single or a plurality of (six in the example illustrated in FIG. 2) air guiding structures 12 are provided at predetermined or certain positions on the substrate body 16. As illustrated in FIG. 1, each of the air guiding structures 12 includes a shaft 40. The shaft 40 includes a cylindrical support member 42 that is fixed to the substrate body 16 and a rotating shaft 44 that is inserted into and is fixed to the cylindrical support member 42.

The cylindrical support member 42 is formed in a substantially cylindrical shape, and its axial direction coincides with a direction normal to the substrate body 16. A parallel surface 48 parallel to the substrate body 16 is formed at the distal end of the cylindrical support member 42 in substantially half of the cylindrical support member 42 in the circumferential direction, and an inclined support surface 50 that is inclined with respect to the parallel surface 48 is further formed at the distal end of the cylindrical support member 42. In the inclined support surface 50, a portion that is farthest away from the parallel surface 48 is a distal end 50T that is positioned farthest away from the substrate body 16.

A baffle plate 46 is mounted on the rotating shaft 44 in a rotatable manner. The baffle plate 46 includes a substantially cylindrical insertion cylinder portion 52 and a pair of plate-like portions 54A and 54B that extend outward in the diameter direction from the insertion cylinder portion 52. An large diameter portion 56 has a diameter that is larger than the inner diameter of the insertion cylinder portion 52. The large diameter portion 56 is formed at the distal end of the rotating shaft 44. The large diameter portion 56 stops the baffle plate 46 from slipping out from the rotating shaft 44 while in a state in which the rotating shaft 44 is inserted into the insertion cylinder portion 52. Moreover, the large diameter portion 56 permits the baffle plate 46 to move along the shaft 40 in the axial direction (the direction of the arrow A1) within the height H1 of the inclined support surface 50 at the least.

When viewed in the axial direction (the direction of the arrow A1), the plate-like portions 54A and 54B extend out from the insertion cylinder portion 52 in opposite directions to each other with a central angle of 180°.

In the plate-like portions 54A, there is formed a weight portion 58 which is a locally thickened end portion of the plate-like portion 54A. When viewed in the axial direction (the direction of the arrow A1), the weight portion 58 deviates the center of gravity G1 of the baffle plate 46 towards the plate-like portion 54A side from the rotation center C1 of the baffle plate 46.

At a portion of the insertion cylinder portion 52 that faces the cylindrical support member 42, a projection 60 projecting towards the cylindrical support member 42 is formed in substantially half of the insertion cylinder portion 52 in the circumferential direction. A surface 60T at the end of the projection 60 is parallel to the substrate body 16 and may come into contact with the parallel surface 48 of the cylindrical support member 42.

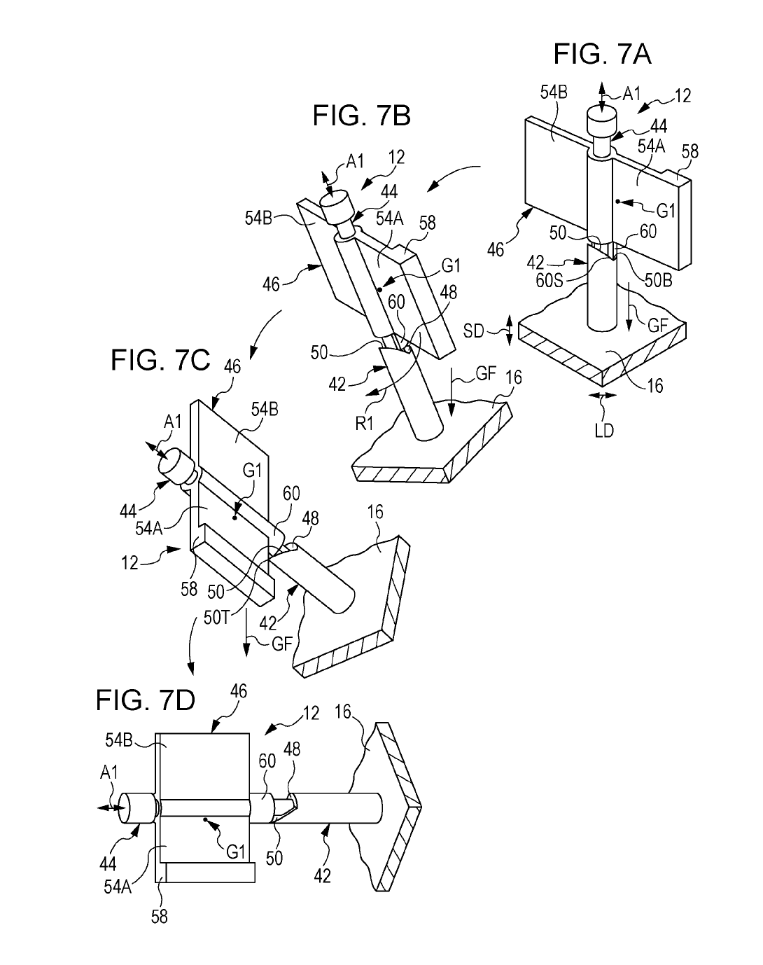

As illustrated in FIG. 7A, in the present exemplary embodiment, when the substrate body 16 is in a horizontal state, in other words, when the shaft 40 extends in the vertical direction, the direction of the gravitational force GF acting on the baffle plate 46 coincides with the axial direction (the direction of the arrow A1) of the shaft 40. Accordingly, the baffle plate 46 is at a position reached after moving downwards in the axial direction (the direction of the arrow A1), and the parallel surface 48 and the surface 60T at the end of the projection 60 are in contact with each other. At this time, as seen in FIG. 6, when seen in the direction normal to the substrate body 16, the position of the parallel surfaces 48 are set so that the baffle plates 46 are each inclined at a predetermined angle with respect to the long sides 16L. Note that in FIGS. 7A to 7D, FIGS. 8A to 8D, FIGS. 10A to 10D, and FIGS. 11A to 11D, the direction along the short side 16S of the substrate body 16 is indicated by the arrow SD, and the direction along the long side 16L is indicated by the arrow LD.

In other words, in FIG. 1, the cylindrical support member 42 is fixed to the substrate body 16 such that the cylindrical support member 42 is at a predetermined or certain angle with respect to the substrate body 16 while having the rotation center C1 at its center.

Furthermore, at this time, as seen in FIG. 7A, a circumferential edge portion 60S of the surface 60T at the end of the projection 60 is in contact with a base end 50B of the inclined support surface 50; accordingly, the rotation of the baffle plate 46 is restricted. In other words, if the baffle plate 46 were to be rotated in such a state, the projection 60 would have to rotate over the inclined support surface 50; accordingly, the rotation is restricted. Accordingly, in the first exemplary embodiment, the projection 60 and the inclined support surface 50 may also be referred to as rotation restricting members 64.

When the substrate body 16 is inclined from the above state into a vertical state such that the short side 16S2 is at the bottom, as illustrated sequentially in FIG. 7B to FIG. 7C, the inclination of the shaft 40 approaches a horizontal state; accordingly, the inclination of the shaft 40 (the direction of the arrow A1) becomes larger with respect to the direction of the gravitational force GF acting on the baffle plate 46.

Since the center of gravity G1 of the baffle plate 46 is deviated from the rotation center C1, when the distal end 50T side becomes lower than the base end 50B side of the inclined support surface 50, the edge portion 60S of the projection 60 slides over the inclined support surface 50 and the baffle plate 46 rotates in the direction of the arrow R1 while being supported by the inclined support surface 50.

As illustrated in FIG. 7D, when the substrate body 16 is in the vertical state with the short side 16S at the bottom, each baffle plate 46 becomes parallel to the long side 16L with the weight portion 58 at the bottom (see FIG. 5). At this time, due to the gravitational force GF acting on the baffle plate 46, the weight portion 58 side, in other words, the plate-like portion 54A side is maintained at the bottom. Moreover, even if the baffle plate 46 attempts to rotate itself from this state, the rotation is restricted due to the gravitational force GF acting on the baffle plate 46. The structure in which the center of gravity G1 of the baffle plate 46 is deviated from the rotation center C1 with the weight portion 58 is an example of the rotation restricting member 64.

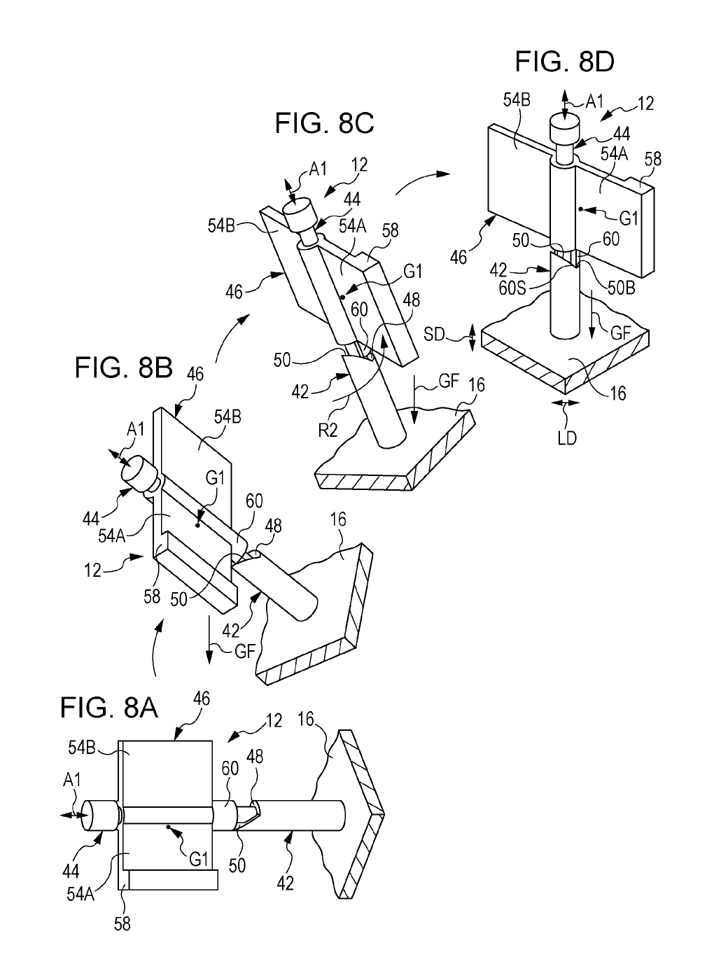

On the other hand, when the substrate body 16 is returned to the horizontal state, that is, when the inclination of the shaft 40 of FIG. 1 approaches the vertical direction, as sequentially illustrated in FIGS. 8A to 8C, the inclination of the shaft 40 (the direction of the arrow A1) becomes smaller with respect to the direction of the gravitational force GF acting on the baffle plate 46. Since the center of gravity G1 of the baffle plate 46 is deviated from the rotation center C1, when the base end 50B side becomes lower than the distal end 50T side of the inclined support surface 50, the edge portion 60S of the projection 60 slides over the inclined support surface 50 and the baffle plate 46 rotates in the direction of the arrow R2 while being supported by the inclined support surface 50. Moreover, as illustrated in FIG. 8D, when the parallel surface 48 and surface 60T at the end of the projection 60 comes into surface contact with each other, each baffle plate 46 becomes inclined at a predetermined or certain angle with respect to the long sides 16L (see FIG. 6).

As illustrated in FIG. 2, each of the cylindrical support members 42 supports the corresponding baffle plate 46 at a predetermined or certain height so that the baffle plates 46 do not come into contact with the elements 38 of the substrate body 16 when the baffle plates 46 are rotated. Note that the height of each element 38 is different according to its type. A height H2 of the cylindrical support member 42 is determined in view of the above point so that the lower ends of the baffle plates 46 are positioned close to the substrate body 16 while the condition that the baffle plates 46 do not come into contact with the elements 38 when the baffle plates 46 are rotated is satisfied.

Furthermore, as seen in FIG. 2 as well, the position of the upper end 40T of each shaft 40 in the height direction (the height H3 from the substrate body 16) is the same throughout the plurality of air guiding structures 12. As illustrated in FIGS. 3 and 4, the height H3 is the upper height limit before the shaft 40 comes into contact with the other substrates 14 and the housing 20T or 20Y when the substrates 14 are mounted in the mounting device 18T or 18Y. Accordingly, regarding each baffle plate 46, the height of the upper end 46T is set high such that the upper end 46T does not come into contact with the other substrates 14 and the wall of the housing 20T or 20Y. As described above, the height of the lower end 46B is set low such that the lower end 46B does not come into contact with the element 38. Determination of the position of the upper end 46T and the position of the lower end 46B of the baffle plate 46 in the above manner allows the baffle plate 46 to have a large area and the air guiding effect to be increased.

A function of the first exemplary embodiment will be described next.

Examples of the mounting device in which the substrates 14 are mounted include, as described above, the vertical mounting device 18T illustrated in FIG. 3 and the horizontal mounting device 18Y illustrated in FIG. 4.

When each substrate 14 is mounted in the vertical mounting device 18T, the weight portions 58 are positioned at the bottom due to gravitational force GF; accordingly, the orientations of the baffle plates 46 are, as illustrated in FIGS. 2 and 5, parallel to the long sides 16L of the substrate body 16. In the vertical mounting device 18T, air WF is introduced from the intake fans 28 that are provided substantially throughout the whole lower area of the mounting areas 22T of each substrate 14. Since the orientation of each of the baffle plates 46 is the same as the flow direction of the air WF, the occurrence of uneven air velocity on the substrate body 16 is suppressed; accordingly, the elements 38 may be cooled effectively.

On the other hand, when each substrate 14 is mounted in the horizontal mounting device 18Y, due to gravitational force GF, each baffle plate 46 moves closer to the substrate body 16, and the surface 60T at the end of the projection 60 comes into surface contact with the parallel surface 48. In other words, as illustrated in FIG. 6, the orientation of each baffle plate 46 of the plurality of air guiding structures 12 is inclined at a predetermined or certain angle with respect to the long sides 16L of each substrate body 16. Moreover, in the horizontal mounting device 18Y, the air WF that has been introduced through the intake port 34 is guided in the desired direction with the baffle plates 46. When the baffle plates 46 are structured so as to be fixed, moreover, when the baffle plates 46 are fixed at an angle that is the same as the angle illustrated in FIG. 5, for example, a risk of uneven air velocity is encountered; however, in the present exemplary embodiment, the occurrence of uneven air velocity is suppressed and the elements 38 may be cooled effectively.

As described above, the substrate 14 of the present exemplary embodiment may guide the air WF along the substrate 14 in an appropriate manner with a single substrate 14 while adapting to the suction and discharge direction of the air WF in both cases, that is, in a case in which the substrate 14 is mounted in the vertical mounting device 18T and in a case in which the substrate 14 is mounted in the horizontal mounting device 18Y. In other words, the structure of the baffle plate 46 does not have to be changed between the vertical mounting device 18T and the horizontal mounting device 18Y; accordingly, the substrate 14 has high versatility. Furthermore, the mounting areas 22T and 22Y of the vertical mounting device 18T and the horizontal mounting device 18Y, respectively, may have a common structure according to the size of the substrate body 16.

Moreover, since the baffle plates 46 are rotated by taking advantage of gravitational force, a personnel that mounts the substrate 14, for example, a maintenance person, only has to, without any particular operation, change the mounting direction (the vertical direction or the horizontal direction) of the substrate 14 in order to change the orientations of the baffle plates 46. As described above, the maintenance person does not have to carry out any operation corresponding to the vertical mounting device 18T and the horizontal mounting device 18Y so as to change the orientations of the baffle plates 46; accordingly, the substrate 14 may have excellent work efficiency.

Furthermore, the center of gravity of the baffle plate 46 is deviated from the rotation center C1, and the inclined support surface 50 supports the insertion cylinder portion 52. Accordingly, the gravitational force acting on the baffle plate 46 may be converted into force that rotates the baffle plate 46; accordingly, the baffle plate 46 may be rotated with a simple structure.

Moreover, the structure in which the center of gravity of the baffle plate 46 is deviated from the rotation center C1 may be achieved with a simple structure provided with merely a weight portion 58 in one of the plate-like portions 54A.

In the present exemplary embodiment, unnecessary rotation of the baffle plate 46 is restricted when air hits the baffle plate 46. Accordingly, the cooling effect of the elements 38 may be maintained in a stable manner. In particular, in a state in which the substrate 14 is mounted in the horizontal mounting device 18Y, air is expected to hit the baffle plate 46 at an oblique angle; even in such a case, the rotation of the baffle plate 46 may be restricted.

In the present exemplary embodiment, the projection 60 formed in the insertion cylinder portion 52 of the baffle plate 46 is in contact with the parallel surface 48 or the inclined support surface 50 of the cylindrical support member 42 fixed to the substrate body 16. Accordingly, the rotation of the baffle plate 46, which utilizes gravitational force, and the restriction of the rotation of the baffle plate 46 in the case in which the substrate body 16 is mounted horizontally may be achieved with the simple structure of the baffle plate 46.

Furthermore, in the present exemplary embodiment, the cylindrical support member 42 is fixed to the substrate body 16, and the rotating shaft 44 is inserted into and is fixed to the cylindrical support member 42. Accordingly, compared with a structure in which the rotating shaft 44 is directly fixed to the substrate body 16, the cylindrical support member 42 is in contact with the substrate body 16 in a large area and, thus, may be fixed in a stable manner.

Moreover, by using the cylindrical support member 42, the parallel surface 48 and the inclined support surface 50 may be formed at the distal end of the cylindrical support member 42 while having a simple structure.

In the substrate 14 of the present exemplary embodiment, the cylindrical support members 42 support the baffle plates 46 so that the baffle plates 46 are at positions that do not come into contact with the elements 38 mounted on the substrate body 16. Accordingly, the baffle plates 46 may be prevented from coming into contact with the elements 38 when the baffle plates 46 rotate.

Moreover, the height of at least one of the cylindrical support members 42 of the plurality of air guiding structures 12 may be different from the height of the other cylindrical support members 42. With such a configuration, when each of the baffle plates 46 rotates, the lower ends of the baffle plates 46 may be positioned close to the substrate body 16 while the condition that the baffle plates 46 do not come into contact with the elements 38 having different heights is satisfied. Accordingly, the baffle plates 46 may extend greatly towards the lower end side while avoiding contact with the elements 38 having different heights, and, thus, the air guiding effect may be increased.

Note that while in the above description, the direction in which the air WF is guided in the vertical mounting device 18T is the direction extending along the long sides 16L of the substrate body 16 (in the vertically upwards direction), the direction in which the air WF is guided may be a direction that extends towards the long sides 16L in an oblique manner depending on, for example, the structure of the intake fans 28 and the arrangement of the elements 38. In such a case, the direction in which the cylindrical support members 42 are fixed to the substrate body 16 may be set so that the baffle plates 46, on which gravitational force is applied, each become oriented to the desired direction with respect to the long sides 16L. For the sake of setting the direction above, for example, it may be achieved by appropriately setting the positional relationships between the surface 60T at the end of the projection 60, and the parallel surface 48 of the cylindrical support member 42 and the base end 50B of the inclined support surface 50.

In a similar manner, the direction in which the air WF is guided in the horizontal mounting device 18Y is not limited to the direction that extends towards the long sides 16L of the substrate body 16 in an oblique manner. For example, the structure and orientation of the cylindrical support member 42 may be set so that the baffle plate 46 is parallel to the long sides 16L when the substrate 14 is mounted in the horizontal mounting device 18Y. That is to say, the direction in which the air WF is guided is not limited to the direction extending along the long sides 16L in the case of the vertical mounting device 18T and to the direction extending towards the long sides 16L in an oblique manner in the case of the horizontal mounting device 18Y.

A description of the second embodiment will be given next. Note that in the second exemplary embodiment, elements, components, and the like that are the same as those of the first embodiment are denoted with the same reference numerals and detailed descriptions thereof are omitted. Furthermore, similar to the first exemplary embodiment, the vertical mounting device 18T and the horizontal mounting device 18Y are included in the mounting device according to the second exemplary embodiment.

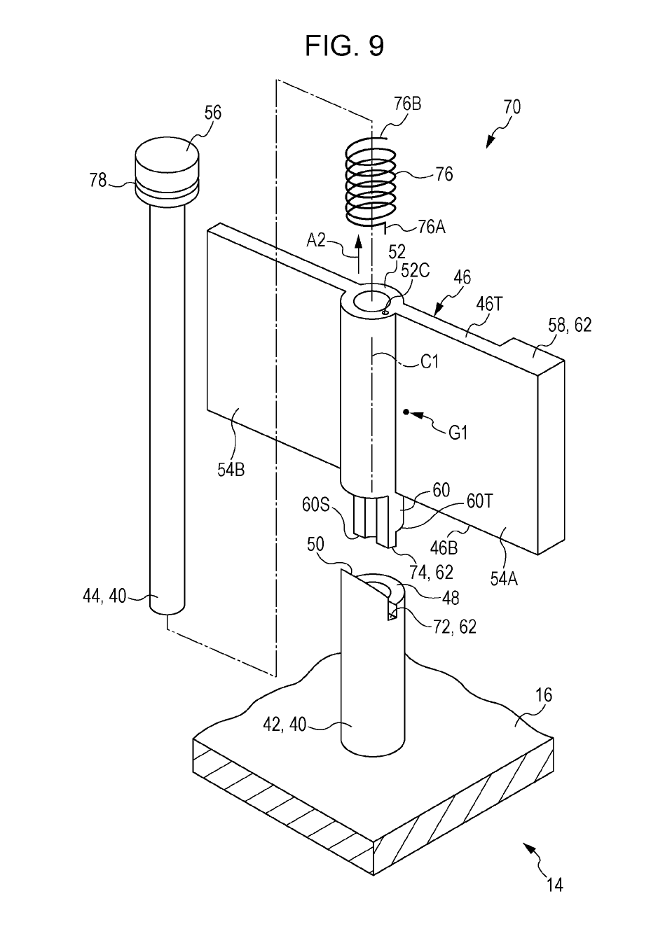

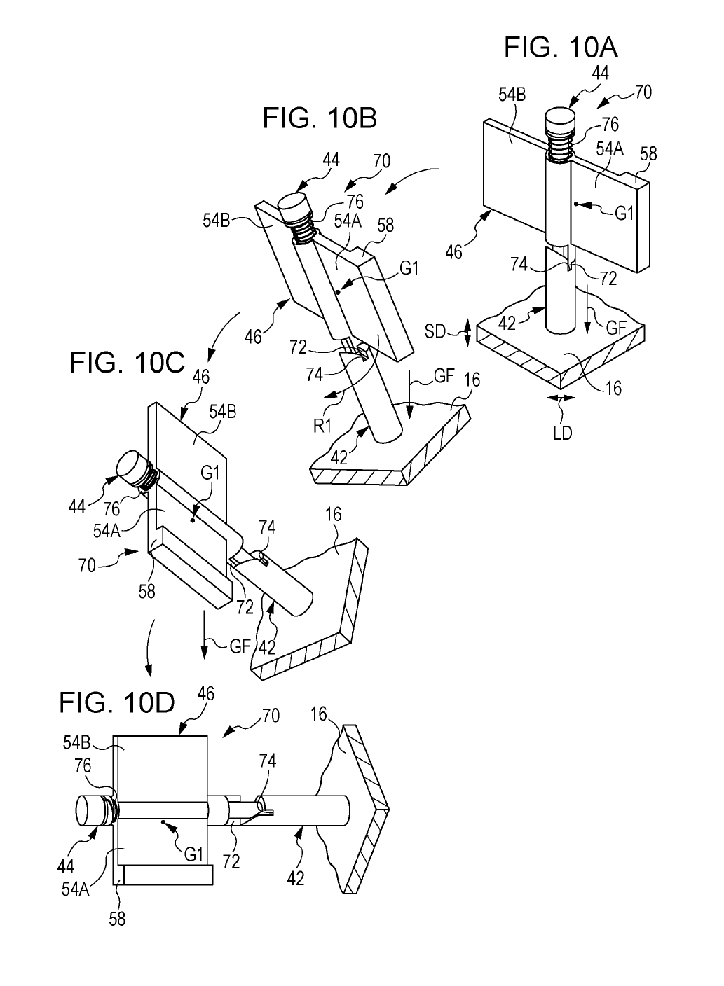

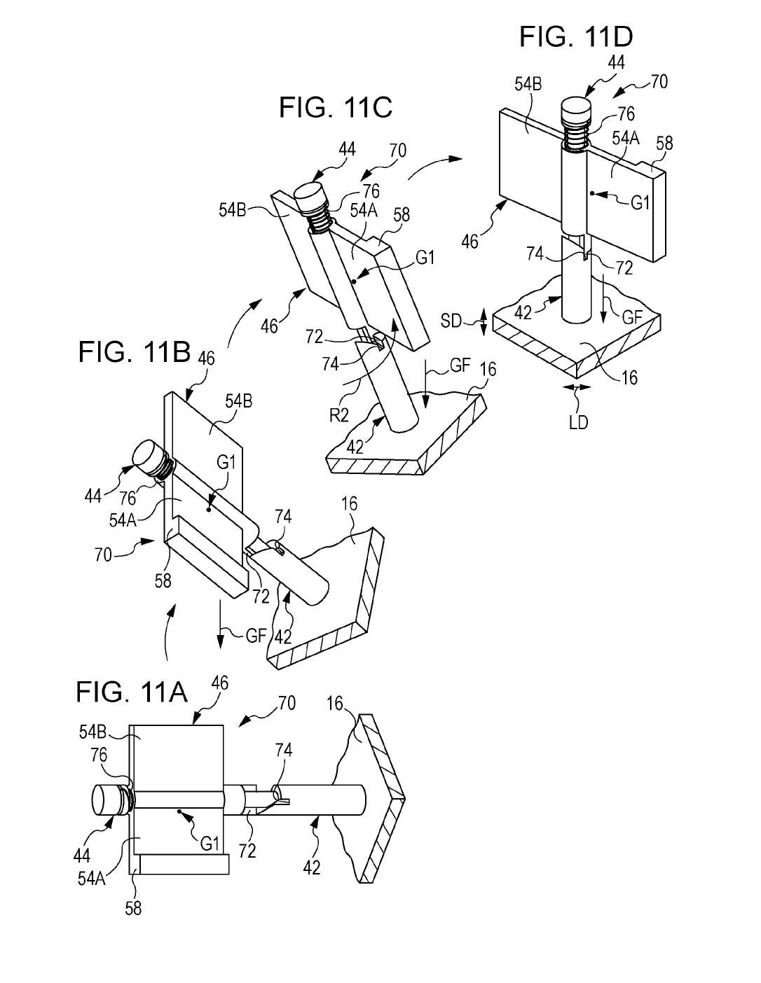

As illustrated in FIG. 9, an air guiding structure 70 of the second exemplary embodiment includes an engagement groove 72 formed in the axial direction at the boundary between the parallel surface 48 and the inclined support surface 50 of the cylindrical support member 42. Furthermore, an engagement protrusion 74 that is engaged with the engagement groove 72 is formed in the insertion cylinder portion 52. As illustrated in FIGS. 10A and 11D, when the engagement protrusion 74 is engaged to the engagement groove 72, the rotation of the baffle plate 46 is stopped. However, when the engagement protrusion 74 is disengaged from the engagement groove 72, the baffle plate 46 becomes rotatable with respect to the cylindrical support member 42 (the shaft 40). The engagement groove 72 and the engagement protrusion 74 are examples of the rotation restricting members.

A coiled spring 76 is mounted between the insertion cylinder portion 52 and the large diameter portion 56 of the rotating shaft 44. The coiled spring 76 of the second exemplary embodiment is a pull spring. An end portion 76A of the coiled spring 76 on the baffle plate 46 side is inserted into and fixed to a fixing hole 52C that is formed in the insertion cylinder portion 52 of the baffle plate 46. On the other hand, an end portion 76B of the coiled spring 76 on the large diameter portion 56 side is received in a rotational manner in a circumferential groove 78 formed in the large diameter portion 56. Accordingly, when the baffle plate 46 rotates, the coiled spring 76 rotates with the baffle plate 46 and, as such, does not hamper the rotation of the baffle plate 46.

The coiled spring 76 applies spring force to the baffle plate 46 in the direction in which the engagement protrusion 74 becomes disengaged from the engagement groove 72 (the direction of the arrow A2). However, the spring force is set so as to be smaller than the gravitational force that acts on the baffle plate 46 when the shaft 40 is in a vertical state.

Accordingly, as illustrated in FIG. 10A, when the substrate 14 is in the horizontal state (the shaft 40 in the vertical state), the baffle plate 46 does not move in the direction of the arrow R1 and the engagement protrusion 74 does not become disengaged from the engagement groove 72 even if the spring force of the coiled spring 76 is applied to the baffle plate 46. The rotation of the baffle plate 46 is restricted. The engagement groove 72 and the engagement protrusion 74 may also be referred to as rotation restricting members 64 in the present exemplary embodiment.

On the other hand, as illustrated in FIGS. 10D and 11D, when the substrate 14 is in the vertical state (the shaft 40 in the horizontal state), the baffle plate 46 is moved in the direction of the arrow A2 due to the spring force of the coiled spring 76. Furthermore, the engagement protrusion 74 is disengaged from the engagement groove 72.

In the second exemplary embodiment including the above-described structure, as illustrated in FIG. 10A, when the substrate 14 is in a horizontal state, in other words, when the substrate 14 is mounted in the horizontal mounting device 18Y, the engagement groove 72 is engaged to the engagement protrusion 74. Furthermore, the baffle plate 46 is inclined at a predetermined inclination angle with respect to the long sides 16L of the substrate body 16 (in the same state as that in FIG. 6). Even if, for example, air hits the baffle plate 46, the rotation of the baffle plate 46 may be restricted and the inclined state may be maintained at the inclination angle.

As illustrated in order from FIG. 10B to FIG. 10C, when the substrate 14 is inclined to the vertical state, in other words, when the substrate 14 is mounted in the vertical mounting device 18T, due to work of the spring force of the coiled spring 76, the engagement protrusion 74 is disengaged from the engagement groove 72 in the course of the inclination process. Furthermore, the baffle plate 46 is capable of being rotated with respect to the shaft 40. When the substrate 14 is in the vertical state, as illustrated in FIG. 10D, the baffle plate 46 may maintain its parallel state with respect to the long sides 16L of the substrate body 16 (in the same state as that in FIG. 5) due to gravitational force acting on the baffle plate 46.

A description of a third embodiment will be given next. Note that in the third exemplary embodiment, elements, components, and the like that are the same as those of the first embodiment are denoted with the same reference numerals and detailed descriptions thereof are omitted. Furthermore, similar to the first exemplary embodiment, the vertical mounting device 18T and the horizontal mounting device 18Y are included in the mounting device according to the third exemplary embodiment.

An air guiding structure 80 of the third exemplary embodiment is illustrated in FIG. 11. The air guiding structure 80 includes the baffle plate 46 in which no weight portion 58 is formed. The center of gravity G1 of the baffle plate 46 and the rotation center C1 coincide with each other when viewed in the axial direction. Accordingly, even if the substrate body 16 is in a vertical state, for example, the baffle plate 46 does not rotate under gravitational force.

No inclined support surface 50 (see FIG. 1, for example) according to the first exemplary embodiment and the second exemplary embodiment is formed at the distal end of the cylindrical support member 42 of the third exemplary embodiment, and a parallel support surface 82 that is parallel to the substrate body 16 is formed throughout the whole circumference.

Furthermore, no projection 60 (see FIG. 1, for example) according to the first exemplary embodiment and the second exemplary embodiment is formed in the lower end of the insertion cylinder portion 52, and a parallel supported surface 84 that is parallel to the substrate body 16 is formed throughout the whole circumference.

A coiled spring 86 is mounted between the insertion cylinder portion 52 and the large diameter portion 56 of the rotating shaft 44. The coiled spring 86 of the third exemplary embodiment is a push spring and pushes the insertion cylinder portion 52 towards the cylindrical support member 42. The pushing makes the parallel support surface 82 and the parallel supported surface 84 come into contact with each other such that a predetermined frictional force acts therebetween. The frictional force restricts the rotation of the baffle plate 46 even when air hits the baffle plate 46. In other words, in the third exemplary embodiment, the structure in which frictional force is made to act between the parallel support surface 82 and the parallel supported surface 84 by pushing the parallel support surface 82 against the parallel supported surface 84 with the coiled spring 86 may also be referred to as the rotation restricting member 64. However, the frictional force is set weak so as to allow the baffle plate 46 to be manually (or with a tool or the like) rotated.

In the third exemplary embodiment having the above structure, the baffle plate 46 is set to its desired orientation manually or by using a tool or the like in both cases, that is, when the substrate 14 is mounted in the vertical mounting device 18T (see FIG. 3) and when the substrate 14 is mounted in the horizontal mounting device 18Y (see FIG. 4). In other words, even in the case of the third exemplary embodiment, air may be guided in the direction for when mounted in the vertical mounting device 18T and in the direction for when mounted in the horizontal mounting device 18Y with a single substrate 14. Since the structure of the baffle plate 46 does not have to be changed between the vertical mounting device 18T and the horizontal mounting device 18Y, the substrate 14 has high versatility.

Note that in the third exemplary embodiment, the structure of the rotation restricting member is not limited to the above structure. For example, the parallel supported surface 84 and the parallel support surface 82 may be provided with an engagement groove 72 and an engagement protrusion 74, respectively (see FIG. 9 for both). In the structure provided with the engagement groove 72 and the engagement protrusion 74, the baffle plate 46 may be configured to be movable in the engagement releasing direction (the direction of the arrow A2 illustrated in FIG. 9) of the engagement protrusion 74 and the engagement groove 72. Furthermore, the coiled spring 86 may be a push spring. With the above, unintended disengagement of the engagement groove 72 and the engagement protrusion 74 may be suppressed and, further, the baffle plate 46 may be rotated after the engagement is released by acting counter to the spring force. In the structure described above, if the engagement groove 72 is set at a plurality of positions that correspond to various rotation angles of the baffle plate 46, the rotation of the baffle plate 46 may be restricted at a plurality of positions.

In the third exemplary embodiment, the adjustment of the rotation angle of the baffle plate 46 may be carried out on-site, where the vertical mounting device 18T or the horizontal mounting device 18Y is mounted, before mounting the substrate 14 in the vertical mounting device 18T or the horizontal mounting device 18Y. Furthermore, when the direction in which the substrate 14 is to be mounted is known in advance, then, for example, the rotation angle of the baffle plate 46 may be adjusted at the stage when the substrate 14 is manufactured at the factory.

In any of the first to third exemplary embodiments, the baffle plate 46 that is rotatable about the shaft 40 may be fabricated while having a simple structure by forming, in the baffle plate 46, the insertion cylinder portion 52 in which the shaft 40 is inserted and the plate-like portions 54A and 54B that extend outward in the diameter direction from the insertion cylinder portion 52.

Now, a description has been given of the exemplary embodiments of the technique disclosed in the present application; however, the technique disclosed in the present application is not limited to the above and it goes without saying that various modifications may be made without departing from the spirit and scope of the disclosure.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An air guiding structure, comprising:
a shaft that is provided on a substrate body in an upright manner;
a baffle plate coupled to the shaft so as to rotate around the shaft, the baffle plate guiding air that has been introduced into the substrate body; and
a rotation restricting member that restricts a rotation of the baffle plate caused by the air that has been introduced.

2. The air guiding structure according to claim 1, wherein
the baffle plate includes
an insertion cylinder portion into which the shaft is inserted, and
a pair of plate-like portions that extend outward in a diameter direction of the shaft from the insertion cylinder portion.

3. The air guiding structure according to claim 2, further comprising
a rotation mechanism that allows the baffle plate to rotate under gravitational force.

4. The air guiding structure according to claim 3, wherein
the rotation mechanism includes
an eccentric member that deviates a position of a center of gravity of the baffle plate from a center of the rotation, and
an inclined support surface that is formed in the shaft, the inclined support surface supporting the insertion cylinder portion and converting the gravitational force that acts on the baffle plate into rotational force of the baffle plate.

5. The air guiding structure according to claim 4, wherein
the eccentric member includes a weight portion provided in the baffle plate.

6. The air guiding structure according to claim 4, further comprising
a projection that projects in an axial direction from a portion of the insertion cylinder portion in the circumferential direction, the projection being in contact with the inclined support surface.

7. The air guiding structure according to claim 4, wherein
the shaft includes
a cylindrical support member in which the inclined support surface is formed, the cylindrical support member being fixed to the substrate body, and
a rotating shaft that is inserted into the insertion cylinder portion and the cylindrical support member.

8. The air guiding structure according to claim 7, wherein
the rotation restricting member includes
engagement members that are each formed in the insertion cylinder portion and the cylindrical support member, the engagement members being engaged with each other to stop the rotation of the baffle plate.

9. The air guiding structure according to claim 8, further comprising
a spring member that applies to the baffle plate a tensile force in a direction that disengages the engagement members, the tensile force being weaker than the gravitational force acting on the baffle plate.

10. A substrate, comprising:
a substrate body on which an element is mounted; and
an air guiding structure including
a shaft that is provided on a substrate body in an upright manner
a baffle plate coupled to the shaft so as to rotate around the shaft, the baffle plate guiding air that has been introduced into the substrate body, and
a rotation restricting member that restricts a rotation of the baffle plate caused by the air that has been introduced.

11. The substrate according to claim 10, wherein
the baffle plate includes
an insertion cylinder portion into which the shaft is inserted, and
a pair of plate-like portions that extend outward in a diameter direction of the shaft from the insertion cylinder portion,
the substrate includes a rotation mechanism that allows the baffle plate to rotate under gravitational force, the rotation mechanism including
an eccentric member that deviates a position of a center of gravity of the baffle plate from a center of the rotation, and
an inclined support surface that is formed in the shaft, the inclined support surface supporting the insertion cylinder portion and converting the gravitational force that acts on the baffle plate into rotational force of the baffle plate,
the shaft includes
a cylindrical support member in which the inclined support surface is formed, the cylindrical support member being fixed to the substrate body, and
a rotating shaft that is inserted into the insertion cylinder portion and the cylindrical support member, and
the cylindrical support member supports the baffle plate such that the baffle plate is spaced apart from the substrate body at a position where the baffle plate does not come into contact with the element mounted on the substrate body when the baffle plate rotates.

12. The substrate according to claim 10, further comprising
a plurality of the cylindrical support members, wherein at least one of the cylindrical support members has a height that is different from the height of the other cylindrical support members.

13. An electronic device, comprising:
a substrate including an air guiding structure that includes
a substrate body on which an element is mounted,
a shaft that is provided on a substrate body in an upright manner,
a baffle plate coupled to the shaft so as to rotate around the shaft, the baffle plate guiding air that has been introduced into the substrate body, and
a rotation restricting member that restricts a rotation of the baffle plate caused by the air that has been introduced;
a housing that holds the substrate in a vertical direction or in a horizontal direction; and
an air introducing device that introduces air to the substrate.
